(19) United States
(12) Patent Application Publication
(10) Pub. No.: US 2026/0134914 A1
(43) Pub. Date: May 14, 2026

(54) MEMORY CIRCUITS WITH SENSE AMPLIFIERS SELECTIVELY COUPLED TO ACCESS LINES AND METHODS FOR OPERATING THE SAME

(71) Applicant: Taiwan Semiconductor Manufacturing Company, Ltd., Hsinchu (TW)

(72) Inventors: Tung-Cheng Chang, New Taipei City (TW); Ku-Feng Lin, Hsinchu City (TW)

(73) Assignee: Taiwan Semiconductor Manufacturing Company, Ltd., Hsinchu (TW)

(21) Appl. No.: 19/080,501

(22) Filed: Mar. 14, 2025

Related U.S. Application Data
(60) Provisional application No. 63/719,851, filed on Nov. 13, 2024.

(51) Int. Cl. G11C 13/00

(52) U.S. Cl. CPC G11C 13/004; G11C 13/0026; G11C 2013/0042

(57) ABSTRACT

A memory circuit includes a first memory cell configured to store a first data bit; a second memory configured to store a second data bit; a sense amplifier coupled to the first memory cell and the second memory cell through a data bit line and a reference bit line, respectively; a first switch; and a second switch. The first switch is selectively coupled between the data bit line and a first input node of the sense amplifier, and the second switch is selectively coupled between the reference bit line and a second input node of the sense amplifier.

### CROSS-REFERENCE TO RELATED APPLICATION

This application claims priority to and the benefit of U.S. Provisional Application No. 63/719,851, filed Nov. 13, 2024, which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example block diagram of a memory circuit, in accordance with some embodiments.

FIG. 2 illustrates an example circuit diagram of a memory cell of the memory circuit of FIG. 1, in accordance with some embodiments.

FIG. 3 illustrates an example circuit diagram of a portion of the memory circuit of FIG. 1, in accordance with some embodiments.

FIG. 4 illustrates waveforms of various signals while operating the memory circuit of FIG. 1, in accordance with some embodiments.

FIGS. 5, 6, and 7 illustrate example circuit diagrams of switches of the memory circuit of FIG. 1, respectively, in accordance with some embodiments.

FIG. 8 illustrates another example circuit diagram of a portion of the memory circuit of FIG. 1, in accordance with some embodiments.

FIG. 9 illustrates an alternative circuit diagram of a sense amplifier of the memory circuit of FIG. 1, in accordance with some embodiments.

FIG. 10 illustrates another alternative circuit diagram of a sense amplifier of the memory circuit of FIG. 1, in accordance with some embodiments.

FIG. 11 illustrates an example flow chart of a method for operating the memory circuit of FIG. 1, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Many modern day electronic devices include electronic memory devices configured to store data. An electronic memory device is typically a volatile memory device or non-volatile memory device. The volatile memory device stores data when it is powered, while the non-volatile memory device is able to store data when power is removed. A resistive random access memory (RRAM) device is one promising candidate for a next generation non-volatile memory technology. The RRAM device has a simple structure, consumes a small cell area, has a low switching voltage and fast switching times, and is compatible with complementary-metal-oxide-semiconductor (CMOS) fabrication processes.

The RRAM device includes a variable resistance dielectric layer arranged between conductive electrodes and is configured to operate based upon a process of reversible switching between resistance states. This reversible switching is enabled by selectively forming a conductive filament through the variable resistance dielectric layer. For example, the variable resistance dielectric layer, which is normally insulating, can be made to conduct by applying a voltage across the conductive electrodes to form a conductive filament extending through the variable resistance dielectric layer. An RRAM cell can have a first (e.g., high) resistance state corresponding to a first data state (e.g., logic ‘0’) and a second (e.g., low) resistance state corresponding to a second data state (e.g., logic ‘1’).

Scaling of the existing RRAM circuits may be limited due to degradation in performance and reliability characteristics. For example, as the size of an RRAM cell (typically formed in the back-end-of-line network) decreases in accordance with transistors (typically formed in the front-end-of-line network), parasitic capacitance across different terminals (e.g., Cgd) of the transistors tends to increase accordingly. The data state stored by an RRAM cell is commonly determined by a sense amplifier, which is formed of some of those transistors formed in the front-end-of-line network. In the existing RRAM circuits, data lines (e.g., bit lines) of the RRAM cell are directly coupled to input nodes of the sense amplifier. Such direct coupling to the input nodes disadvantageously narrows a read window of the RRAM cell. This issue becomes increasingly critical, as the parasitic capacitance increases with the scaling trend. Thus, the existing RRAM circuits have not been entirely satisfactory in certain aspects.

The present disclosure provides various embodiments of a memory circuit including a sense amplifier that has its input nodes selectively coupled to data lines of one or more corresponding memory cells. In some embodiments, the memory cell of the disclosed memory circuit may include an RRAM cell. However, it should be appreciated that the memory cell can be any of various other non-volatile memory cells, e.g., a magnetoresistive random access memory (MRAM) cell, a spintronic memory cell, a one-time-programmable (OTP) memory cell, etc., or volatile memory cells, e.g., a static random access memory (SRAM) cell, while remaining within the scope of the present disclosure. The sense amplifier may include a pair of cross-coupled inverters, with two input nodes that are selectively coupled to a pair of access lines (e.g., a data line and a reference line), respectively. For example, during an evaluation phase, the input nodes are coupled to the access lines, while the input nodes are decoupled from the cross-coupled inverters; and during a latch phase, the input nodes are decoupled from the access lines, while the input nodes are coupled to the cross-coupled inverters. By selectively coupling the input nodes to the access lines, a data bit stored in the input node(s) can be advantageously immune from being contaminated by parasitic capacitance, if any. As a result, even following the trend to scale down dimensions of the transistors, the disclosed memory circuit may not suffer the above-identified issues.

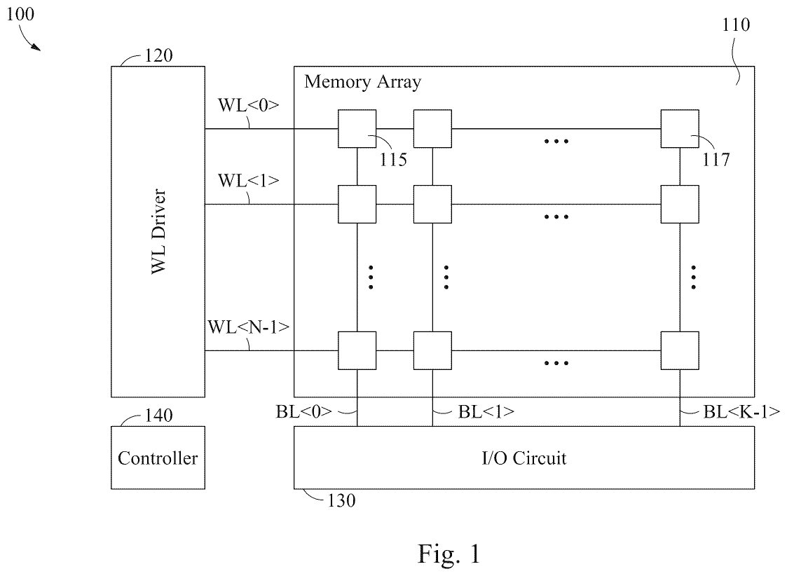

FIG. 1 illustrates an example block diagram of a memory circuit 100, in accordance with various embodiments of the present disclosure. As shown, the memory circuit 100 includes one or more memory arrays 110, a word line (WL) driver 120, and an input/output (I/O) circuit 130, and a memory controller 140. It should be appreciated that the block diagram of FIG. 1 has been simplified for illustrative purposes, and thus, the memory circuit 100 can include any of various other components, e.g., a sinker, a source line (SL) driver, a pre-charge circuit, etc., while remaining within the scope of the present disclosure.

The memory array 110 includes a plurality of first storage circuits or first memory cells 115 and a plurality of second storge circuits of second memory cells 117, which may be arranged in two-dimensional or three-dimensional arrays. In some embodiments, each of the first memory cells 115 and the second memory cells 117 includes an RRAM cell. However, each of the first/second memory cells 115/117 can include any of various other configuration of memory cells, while remaining within the scope of the present disclosure. For example, each of the first/second memory cells 115/117 can include an MRAM cell, a spintronic memory cell, an OTP memory cell, or an SRAM cell.

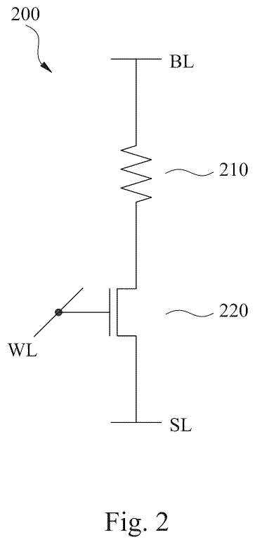

As will be shown below in FIG. 2, each of the first/second memory (RRAM) cells 115/117 can be implemented as a 1-transistor-1-resistor (1T1R) structure, e.g., a resistor with variable resistance serially connected to a transistor. Each of the first/second memory cells 115/117 of the memory array 110 may be coupled to a corresponding word line WL and a corresponding bit lines BL. For example, the memory array 110 includes a number of word lines WLs, e.g., WL<0>, WL<1>... WL<N-1>, disposed across multiple rows, respectively. The number “N” can be any integer. Each of the word lines WLs can extend in a first direction. The memory array 110 further includes a number of bit lines BLs, e.g., BL<0>, BL<1>... BL<K-1>, disposed across multiple columns, respectively. The number “K” can be any integer. Each of the bit lines BLs can extend in a second direction perpendicular to the first direction.

In some embodiments, the first memory cells 115 are each configured to store a data bit corresponding to either a high resistance state (high resistance) or a low resistance state (low resistance), while the second memory cells 117 are each configured to provide a reference resistance between the high resistance and the low resistance. The first memory cell 115 and second memory cell 117 are sometimes referred to as “data cell 115” and “reference cell 117,” respectively. As will be discussed below, the each of the data cells 115, with a corresponding one of the reference cells 117, are coupled to a sense amplifier (of the I/O circuit 130), in which the corresponding reference cell 117 is configured to provide a reference signal (e.g., voltage, current) for the sense amplifier to identify or otherwise determine the logic state of a data bit stored by the data cell 115. In some embodiments, the second memory cells 117 can be disposed along one or more of the K columns (sometimes referred to as “reference columns”), while the first memory cells 115 can be disposed along the rest of the K columns (sometimes referred to as “data columns”).

The memory controller 140 is a hardware component that can control (e.g., read) operations of the memory array 110 through the WL controller 120 and/or the I/O circuit 130. The WL driver circuit 120 and the I/O circuit 130 may each be embodied as one or more logic circuits, one or more analog circuits, or a combination of them. In some embodiments, the WL driver circuit 120 is a circuit that can provide a voltage or current (e.g., a WL assertion signal with one or more pulses) through an asserted word line WL of the memory array 110, and the I/O circuit 130 is a circuit that can provide or sense a voltage or current through one or more bit lines BLs of the memory array 110. As will be discussed in further detail below, the I/O circuit 130 can include a number of sense amplifiers. Each of the sense amplifiers can be coupled to a reference cell 117 and a data cell 115 through a pair of bit lines BLs (sometime referred to as a “reference bit line RBL” and a data bit line DBL,” respectively), in which the sense amplifier has a pair of input nodes selectively coupled to the reference bit line RBL and data bit line DBL through a first switch and a second switch, respectively. In some other embodiments, the memory circuit 100 can include more, fewer, or different components than shown in FIG. 1. For example, the memory circuit 100 can further include a timing controller that can provide control signals or clock signals to synchronize operations of the WL driver circuit 120 and the I/O circuit 130.

FIG. 2 illustrates an example circuit diagram of one memory cell (hereinafter “memory cell 200”) of the memory array 110, in accordance with some embodiments of the present disclosure. In FIG. 2, the memory cell 200, including a transistor and a variable resistor connected in series (1T1R), can represent a configuration of the data cell 115 and/or the reference cell 117, in some embodiments. It, however, should be appreciated that the circuit diagram of FIG. 2 is provided merely for illustrative purpose, and does not intend to limit the scope of the present disclosure.

As shown, the memory cell 200 includes a variable resistor 210 and an access transistor 220 that are connected in series. The variable resistor 210 can present a resistance state that is switchable between a low resistance state (LRS) and a high resistance state (HRS). The resistance state is indicative of a data value (e.g., a logic “1” or logic “0”) stored within the memory cell 200. Further, a first terminal of the variable resistor 210 is connected to a bit line BL, a second terminal of the variable resistor 210 is connected to a first source/drain terminal of the access transistor 220, a gate terminal of the access transistor 220 is connected to a word line WL, and a second source/drain terminal of the access transistor 220 is connected to a source line SL which is typically connected to ground. With this configuration, the access transistor 220 can be activated (e.g., turned on) by asserting the word line WL such as, for example, applying a signal with logic 1 on the gate terminal of the access transistor 220. Upen being activated, another signal can be applied on the bit line BL to read or write the variable resistor 210.

In some embodiments, the access transistor 220 can be formed in the front-end-of-line network, while the variable resistor 210 may be formed in the back-end-of-line network. In some other embodiments, both of the access transistor 220 and the variable resistor 210 can be formed in the back-end-of-line network. Generally, the front-end-of-line network refers to structures formed along the major surface of a semiconductor substrate, and the back-end-of-line network refers to structures formed in metallization layers disposed over the major surface of the semiconductor substrate.

The variable resistor 210 typically includes a resistive switching element/variable resistive dielectric layer sandwiched between a top electrode and a bottom electrode. In some embodiments, the top electrode comprises titanium (Ti) and tantalum nitride (TaN), the bottom electrode comprises titanium nitride (TiN), and the variable resistive dielectric layer comprises nickel oxide (NiO), titanium oxide (TiO), hafnium oxide (HfO), zirconium oxide (ZrO), zinc oxide (ZnO), tungsten oxide (WO₃), aluminum oxide (Al₂O₃), tantalum oxide (TaO), molybdenum oxide (MoO), or copper oxide (CuO), for example. In some embodiments, the bottom electrode can be formed in a lower one of the metallization layers, and the top electrode can be formed in a higher one of the metallization layers. Further, a top electrode via (TEVA) can be formed over the top electrode, and a bottom electrode via (BEVA) can be formed below the bottom electrode, allowing the variable resistor 210 to connect to other structures/components such as, the access transistor 220, the bit line BL, etc.

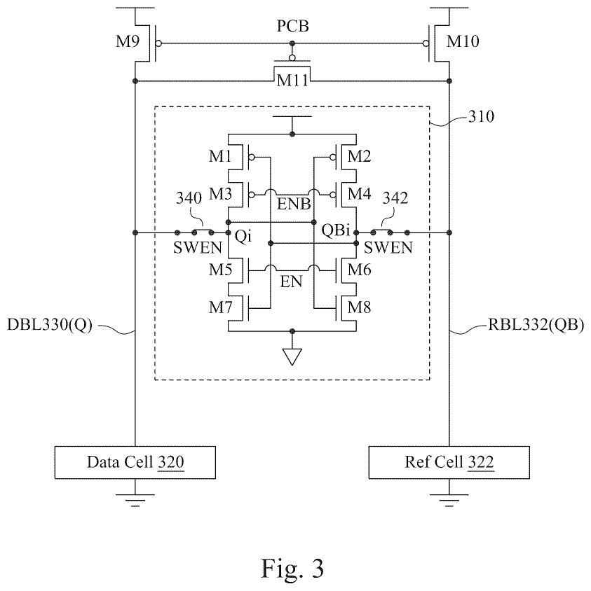

FIG. 3 illustrates an example circuit diagram of a portion of the memory circuit 100, in accordance with some embodiments of the present disclosure. For example, the circuit of FIG. 3 illustrates one of the sense amplifiers of the I/O circuit 130 (hereinafter “senser amplifier 310”), which is coupled to one of the data cells of the memory array 110 (hereinafter “data cell 320”) and one of the reference cells of the memory array 110 (hereinafter “reference cell 322”).

Each of the data cell 320 and reference cell 322 can be constructed similarly to the memory cell 200 (FIG. 2), e.g., having an 1TIR configuration. However, the data cell 320, similar to the data cell 115, can be programmed with a HRS (e.g., logic 0) or a LRS (e.g., logic 1), while the reference cell 322, similar to the reference cell 117, is configured to be programmed with a constant resistance state that is between the HRS and the LRS. Stated another way, the data cell 320 can conduct a relative low current when programmed with the HRS and conduct a relatively high current when programmed with the LRS, while the reference cell 322 can conduct a constant current between the relatively high current and the relatively low current.

As shown, the sense amplifier 310 is coupled to the data cell 320 and the reference cell 322 through a data bit line DBL 330 and a refence bit line RBL 332, respectively. The sense amplifier 310 is coupled to the data bit line DBL 330 and the refence bit line RBL 332 through a first switch 340 and a second switch 342, respectively. Further, the data bit line DBL 330 is selectively coupled to a first input node “Qi” of the sense amplifier 310 through the first switch 340, and the refence bit line RBL 332 is selectively coupled to a second input node “QBi” of the sense amplifier 310 through the second switch 342, in some embodiments. When the first switch 340 is activated, the input node Qi is connected to the data bit line DBL 330; and when the first switch 340 is deactivated, the input node Qi is disconnected from the data bit line DBL 330. Similarly, when the second switch 342 is activated, the input node QBi is connected to the reference bit line RBL 332; and when the second switch 342 is deactivated, the input node QBi is disconnected from the reference bit line RBL 332. As will be discussed below, both of the first switch 340 and second switch 342 can be activated/deactivated by a common switch enable (SWEN) signal that can transition from a first logic state to a second logic state based on a signal (QB signal) present on the refence bit line RBL 332.

The sense amplifier 310, as disclosed herein, can include transistors M1, M2, M3, M4, M5, M6, M7, and M8. The transistors M1 to M4 may each be implemented as a p-type metal-oxide-semiconductor (MOS) transistor, and the transistors M5 to M8 may each be implemented as an n-type MOS transistor. It should be understood that the transistors M1 to M8 can be implemented as any of various other type of transistors, while remaining within the scope of the present disclosure. In some embodiments, the transistors M1, M2, M7, and M8 can “conditionally” form a pair of cross-coupled inverters, when the transistors M3 to M6 are activated (or turned on). The transistors M3 to M6 may sometimes be referred to as input transistors, where the transistors M3 and M5 form a first pair of input transistors and the transistors M4 and M6 form a second pair of input transistors.

When the transistors M3 to M6 are activated, the transistors M3 to M6 can each form a conduction path between its two source/drain terminals. For example, when the transistor M3 is activated, its first and second source/drain terminals, forming a short circuit (or a first conduction path), are both connected to the input node Qi; and when the transistor M3 is deactivated, the first and second source/drain terminals are disconnected from each other, with the first source/drain terminal connected to the transistor M1 and the second source/drain terminal connected to the input node Qi, respectively. When the transistor M4 is activated, its first and second source/drain terminals, forming a short circuit (or a second conduction path), are both connected to the input node QBi; and when the transistor M4 is deactivated, the first and second source/drain terminals are disconnected from each other, with the first source/drain terminal connected to the transistor M2 and the second source/drain terminal connected to the input node QBi, respectively. When the transistor M5 is activated, its first and second source/drain terminals, forming a short circuit (or a third conduction path), are both connected to the input node Qi; and when the transistor M5 is deactivated, the first and second source/drain terminals are disconnected from each other, with the second source/drain terminal connected to the transistor M7 and the first source/drain terminal connected to the input node Qi, respectively. When the transistor M6 is activated, its first and second source/drain terminals, forming a short circuit (or a fourth conduction path), are both connected to the input node QBi; and when the transistor M6 is deactivated, the first and second source/drain terminals are disconnected from each other, with the second source/drain terminal connected to the transistor M8 and the first source/drain terminal connected to the input node QBi, respectively.

A first source/drain terminal of the transistor M1 is connected to VDD, and a second source/drain terminal of the transistor MI can be coupled to the input node Qi through the first conduction path formed by the activated transistor M3; a first source/drain terminals of the transistor M2 is connected to VDD, and a second source/drain terminal of the transistor M2 can be coupled to the input node QBi through the second conduction path formed by the activated transistor M4; a first source/drain terminal of the transistor M7 is connected to VSS, and a second source/drain terminal of the transistor M7 can be coupled to the input node Qi through the third conduction path formed by the activated transistor M5; and a first source/drain terminal of the transistor M8 is connected to VSS, and a second source/drain terminal of the transistor M8 can be coupled to the input node QBi through the fourth conduction path formed by the activated transistor M6. Further, respective gate terminals of the transistors M1 and M7 are connected to each other and further coupled to the input node QBi, and respective gate terminals of the transistors M2 and M8 are connected to each other and further coupled to the input node Qi. As such, a first inverter, formed by the transistors M1 and M7, and a second inverter, formed by the transistors M2 and M8, can be cross-coupled to each other. The first inverter can have an input at the input node QBi and an output at the input node Qi; and the second inverter can have an input at the input node Qi and an output at the input node QBi.

In some embodiments, the transistors M3 and M4 can be turned on/off by a first enable (ENB) signal, e.g., with their gate terminals configured to receive the ENB signal; and the transistors M5 and M6 can be turned on/off by a second enable (EN) signal, e.g., with their gate terminals configured to receive the EN signal. The EN and ENB signals are logically opposite to each other, and thus, the pair of transistors M3 and M4 and the pair of transistors M5 and M6 can be alternately turned on. As will be discussed below, the EN/ENB signal can transition from a first logic state to a second logic state based on a signal (QB signal) present on the refence bit line RBL 332.

Also illustrated in FIG. 3, the memory circuit 100 further includes transistors M9, M10, and M11 that operatively serve as a pre-charge circuit. The transistors M9 to M11 may each be implemented as a p-type MOS transistor, with their gate terminals configured to receive a pre-charge (PCB) signal. When activated by the PCB signal (e.g., during a pre-charge phase), the transistor M11 can serve as an equalizer, and the transistors M9 and M10 can respectively charge the signal (Q signal) present on the data bit line DBL 330 and the signal (QB signal) present on the reference bit line RBL 332 to VDD (or logic 1). As will be discussed below, such a pre-charge phase of the memory circuit 100 can occur prior to an evaluation phase of the memory circuit 100.

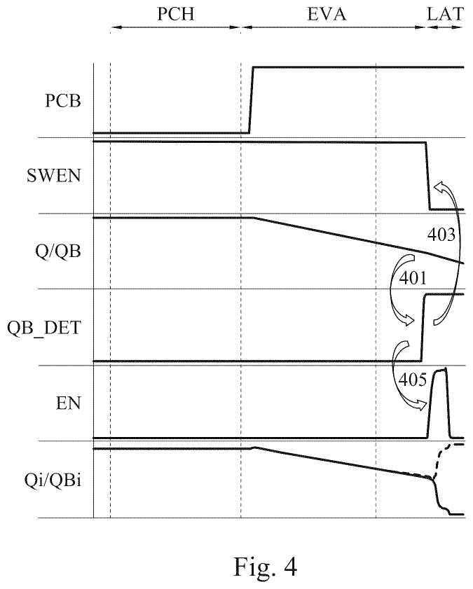

FIG. 4 illustrates example waveforms of some of the above-identified signals varying over time, for operating the memory circuit 100 (FIG. 1) or the sense amplifier 310 (FIG. 3), in accordance with some embodiments of the present disclosure. For example, the waveforms of the PCB signal, the SWEN signal, the Q signal, the QB signal, a QB_DET signal, the EN signal, a signal present on the input node Qi (hereafter “Qi signal”), and a signal present on the input node QBi (hereafter “QBi signal”) are shown. Generally, the waveforms shown in FIG. 4 include three different operation phases of the memory circuit 100, for example, a pre-charge (PCH) phase, an evaluation (EVA) phase, and a latch (LAT) phase.

During the PCH phase, the PCB signal, SWEN signal, and EN signal are provided at logic 0, logic 1, and logic 0, respectively. As such, the transistors M9 to M11 (of the pre-charge circuit) can be turned on, such that the Q signal and the QB signal are both pre-charged (or charged) to VDD (or logic 1). In some embodiments, the QB_DET signal may remain at logic 0 as long as the QB signal drops to a certain voltage level. Further, since the EN signal is at logic 0 (and the ENB signal is at logic 1), the transistors M3 to M6 are all turned off; and the SWEN signal is at logic 1, the switches 320 and 342 are activated. Accordingly, the input nodes Qi and QBi may be coupled to the data bit line DBL 330 and the refence bit line RBL 332, respectively, while being isolated given that no conduction path is formed across the source/drain terminals of any of the transistors M3 to M6.

During the EVA phase, the PCB signal, SWEN signal, and EN signal are provided at logic 1, logic 1, and logic 0, respectively. As such, the transistors M9 to M11 (of the pre-charge circuit) can be turned off, causing the data bit line DBL 330 and the refence bit line RBL 332 to be decoupled from VDD. Since the EN signal is at logic 0 (and the ENB signal is at logic 1), the transistors M3 to M6 are all turned off; and the SWEN signal is at logic 1, the switches 320 and 342 are activated. Accordingly, the input nodes Qi and QBi may be coupled to the data bit line DBL 330 and the refence bit line RBL 332, respectively. Stated another way, the signals present at the input node Qi and on the data bit line DBL 330 are the same, and the signals present at the input node QBi and on the reference bit line RBL 332 are the same. In some embodiments, the input nodes Qi and QBi may be referred to as being isolated, given that no conduction path is formed across the source/drain terminals of any of the transistors M3 to M6. This can advantageously solve the issues of parasitic coupling from one or more of the transistors M1, M2, M7, and M8. As the data bit line DBL 330 and the refence bit line RBL 332 are each decoupled from VDD, the Q signal (equal to the Qi signal) and the QB signal (equal to the QBi signal) can drop from VDD (or logic 1), with respective discharging rates based on the currents conducting through the data cell 320 and the reference cell 322, respectively.

During the LAT phase, the PCB signal, SWEN signal, and EN signal are provided at logic 1, logic 0, and logic 1, respectively. As such, the transistors M9 to M11 (of the pre-charge circuit) can be turned off, causing the data bit line DBL 330 and the refence bit line RBL 332 to be decoupled from VDD. Since the EN signal is at logic 1 (and the ENB signal is at logic 0), the transistors M3 to M6 can be turned on, which causes each of the transistors M3 to M6 to form a conduction path, in some embodiments. Accordingly, the transistors M1, M2, M7, and M8 can operatively form a pair of cross-coupled inverters. Since the SWEN signal is at logic 0, the switches 320 and 342 are deactivated, which causes the input nodes Qi and QBi to be decoupled from the data bit line DBL 330 and the refence bit line RBL 332, respectively. The cross-coupled inverters can thus latch and amplify the difference between the Qi signal and the QBi signal (evaluated at the EVA phase). In some embodiments, upon the QB signal dropping to a sufficiently low voltage level, e.g., VDD/2 (as indicated by symbolic arrow 401), the QB_DET signal may transition from logic 0 to logic 1; upon the QB_DET signal switching to logic 1, the SWEN signal may transition to logic 1 and the EN signal may transition to logic 1 (as indicated by symbolic arrows 403 and 405, respectively).

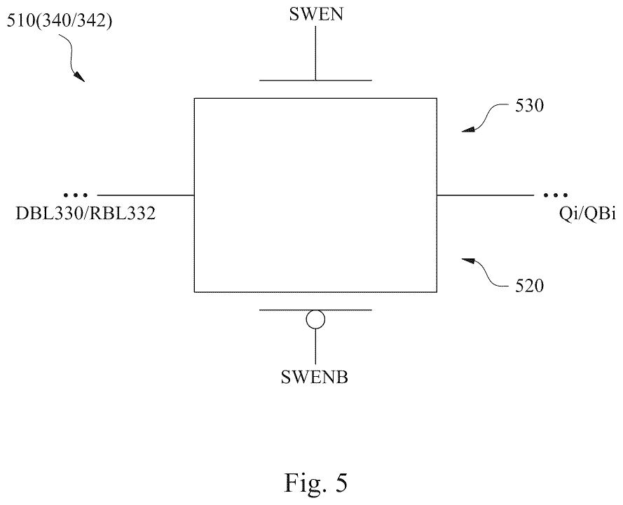

FIGS. 5, 6, and 7 illustrate example circuit diagrams of the first switch 340 and second switch 342, respectively, in accordance with some embodiments of the present disclosure. It should be understood that the circuit diagrams of FIGS. 5-7 are provided merely for illustrative purposes, and do not intend to limit the scope of the present disclosure.

In FIG. 5, each of the first switch 340 and second switch 342 can be implemented as a transmission gate 510. For example, the transmission gate 510 includes a p-type transistor 520 and an n-type transistor 530, with their first source/drain terminals connected to each other and their second source/drain terminals connected to each other. The first source/drain terminals may be connected to the data bit line DBL 330 (or the reference bit line RBL 332), and the second source/drain terminals may be connected to the input node Qi (or the input node QBi). Gate terminals of the n-type transistor 530 and p-type transistor 520 are configured to receive the SWEN signal and a logically inverted version of the SWEN signal (SWENB signal), respectively.

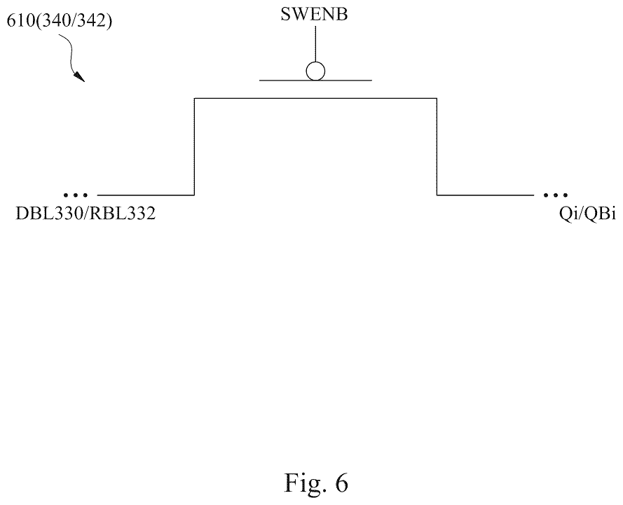

In FIG. 6, each of the first switch 340 and second switch 342 can be implemented as a p-type transistor 610. A first source/drain terminal of the transistor 610 may be connected to the data bit line DBL 330 (or the reference bit line RBL 332), and a second source/drain terminal of the transistor 610 may be connected to the input node Qi (or the input node QBi). A gate terminal of the transistor 610 is configured to receive a logically inverted version of the SWEN signal (SWENB signal).

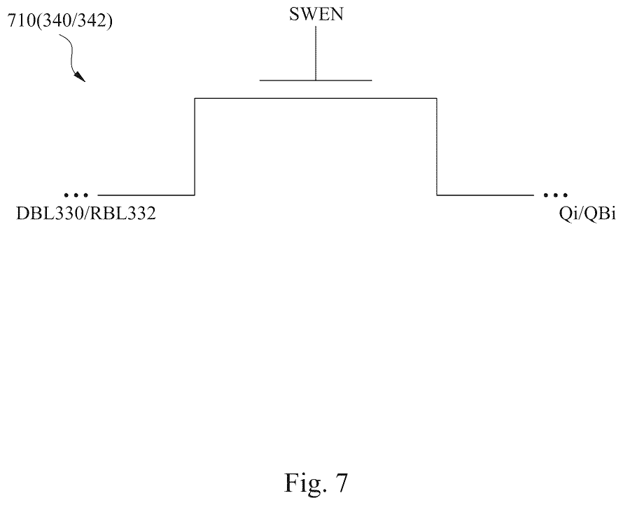

In FIG. 7, each of the first switch 340 and second switch 342 can be implemented as an n-type transistor 710. A first source/drain terminal of the transistor 710 may be connected to the data bit line DBL 330 (or the reference bit line RBL 332), and a second source/drain terminal of the transistor 710 may be connected to the input node Qi (or the input node QBi). A gate terminal of the transistor 710 is configured to receive the SWEN signal.

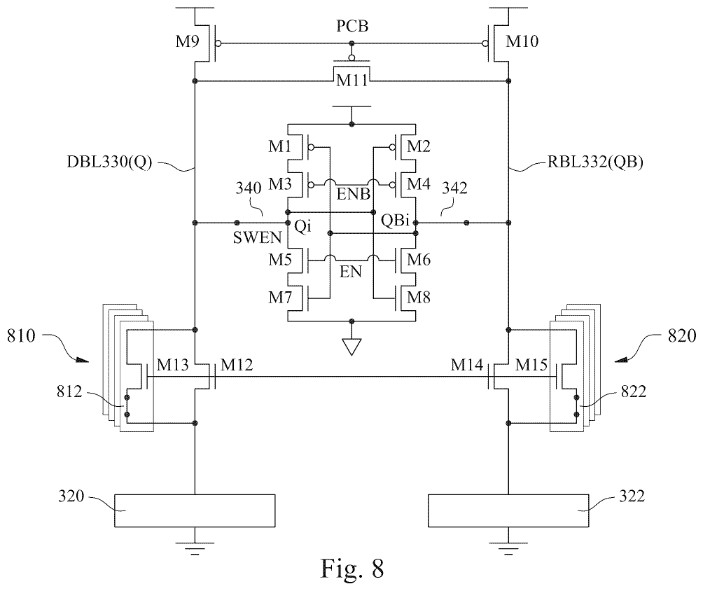

FIG. 8 illustrates another example circuit diagram of a portion of the memory circuit 100, in accordance with some embodiments of the present disclosure. For example, the circuit diagram of FIG. 8 is substantially similar to the circuit diagram of FIG. 3, except that the circuit diagram of FIG. 8 includes a first trimming circuit 810 and a second trimming circuit 820. Accordingly, the following discussion will be focused on the difference and the reference numerals of FIG. 3 will be again used.

As shown, the trimming circuit 810 is coupled between the data bit line DBL 330 and the data cell 320, and the trimming circuit 820 is coupled between the reference bit line RBL 332 and the reference cell 330. The trimming circuit 810 can adjust a level of the signal present on the data bit line DBL 330 by activating one or more of its transistors, and the trimming circuit 820 can adjust a level of the signal present on the reference bit line RBL 332 by activating one or more of its transistors. For example, the trimming circuit 810 can include transistors M12, and one or more transistors M13, where each of the one or more transistors M13 is coupled with a respective switch 812; and the trimming circuit 820 can include transistors M14, and one or more transistors M15, where each of the one or more transistors M15 is coupled with a respective switch 822. All the transistors of the trimming circuits 810 and 820 may have their gate terminals connected to a common signal. However, the one or more transistors M13 may each selectively provide a current flowing through the data bit line DBL 330, and the one or more transistors M15 may each selectively provide a current flowing through the reference bit line RBL 332.

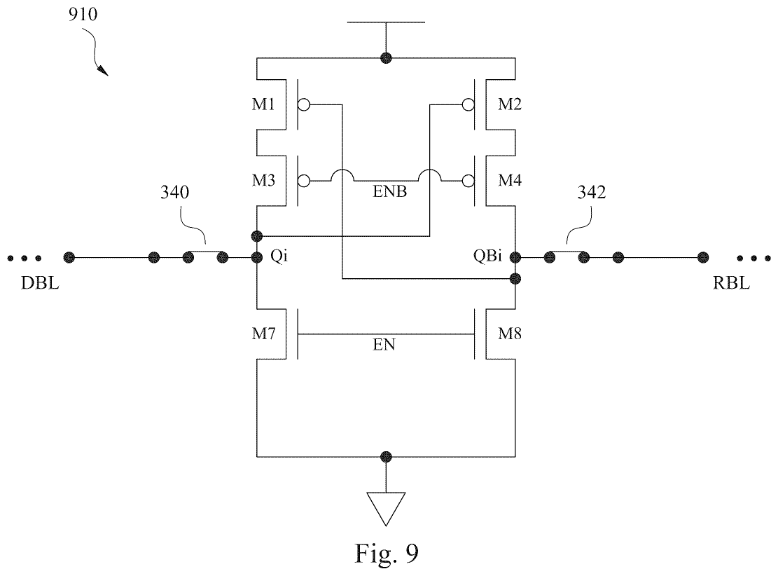

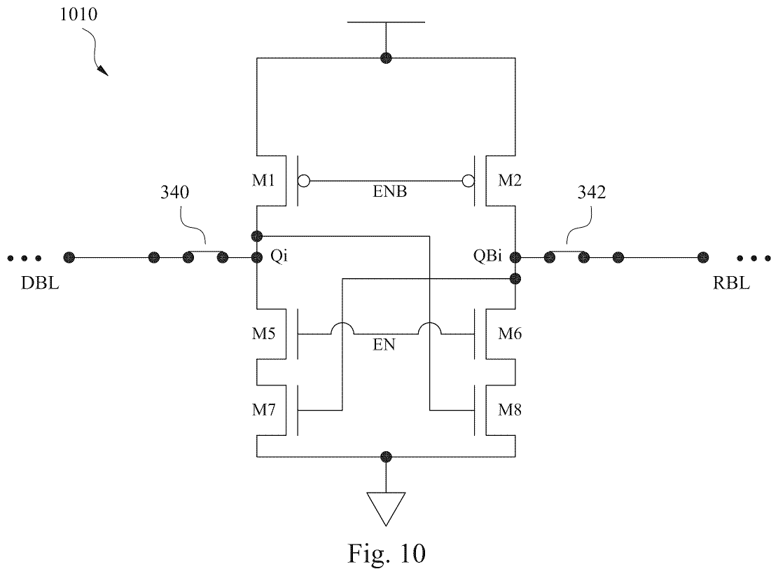

FIG. 9 and FIG. 10 illustrate other example circuit diagrams 910 and 1010 of the sense amplifier of the I/O circuit 130 (hereinafter “sense amplifier 910” and “sense amplifier 1010”), respectively, in accordance with some embodiments of the present disclosure. Each of the sense amplifiers 910-1010 is substantially similar to the sense amplifier 310 shown in FIG. 3, except that the sense amplifier 910 has only p-type input transistors and the sense amplifier 1010 has only n-type input transistors. Accordingly, the following discussion will be focused on the difference and some of the reference numerals of FIG. 3 will be again used.

In FIG. 9, the sense amplifier 910 also includes the transistors M1-M2 and M7-M8 that operatively serve as a pair of cross-coupled inverters, but includes only the p-type input transistors M3-M4. As such, while remaining selectively coupled to the data bit line DBL 330 through the switch 340, the input node Qi is connected to the second source/drain terminal of the transistor M3 and directly connected to the first source/drain terminal of the transistor M7; and remaining selectively coupled to the reference bit line RBL 332 through the switch 342, the input node QBi is connected to the second source/drain terminal of the transistor M4 and directly connected to the first source/drain terminal of the transistor M8.

In FIG. 10, the sense amplifier 1010 also includes the transistors M1-M2 and M7-M8 that operatively serve as a pair of cross-coupled inverters, but includes only the n-type input transistors M5-M6. As such, while remaining selectively coupled to the data bit line DBL 330 through the switch 340, the input node Qi is directly connected to the second source/drain terminal of the transistor M1 and connected to the first source/drain terminal of the transistor M5; and remaining selectively coupled to the reference bit line RBL 332 through the switch 342, the input node QBi is directly connected to the second source/drain terminal of the transistor M2 and connected to the first source/drain terminal of the transistor M6.

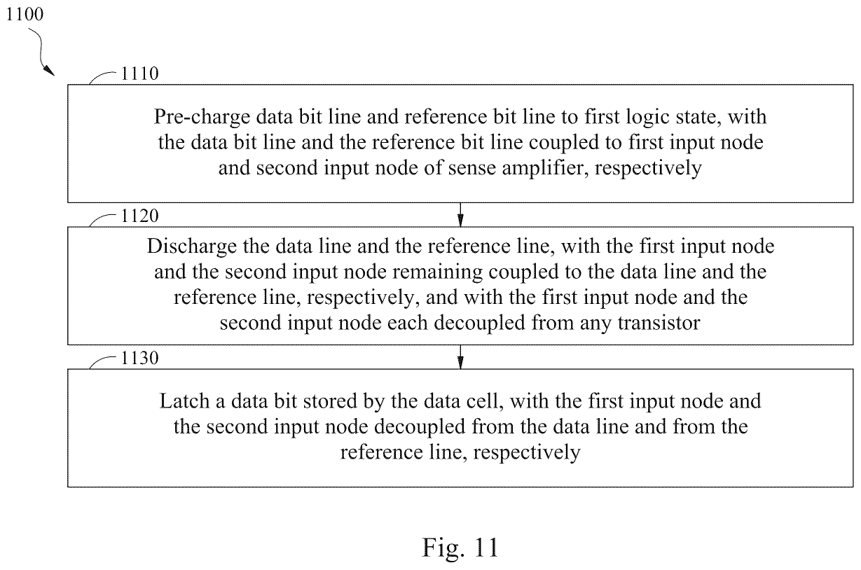

FIG. 11 illustrates a flow chart of an example method 1100 for operating a memory circuit, in accordance with some embodiments of the present disclosure. For example, at least some of the operations (or steps) of the method 1100 can be used to read a data bit stored by the data cell 115 of the memory circuit 100 (FIG. 1). The data bit can be read (or determined) by any of the disclosed sense amplifier, e.g., sense amplifier 310. It is noted that the method 1100 is merely an example, and is not intended to limit the scope of the present disclosure. Accordingly, it should be understood that additional operations may be provided before, during, and/or after the method 1100 of FIG. 11, and that some other operations may only be briefly described herein.

The method 1100 starts with operation 1110 of pre-charging a data bit line and a reference bit line to a first logic state, with the data bit line and the reference bit line coupled to a first input node and a second input node of a sense amplifier, respectively. In some embodiments, the data bit line is coupled to a data cell while the reference line is coupled to a reference bit cell. Using the memory circuit 100 (and one of its implementations shown in FIG. 3) as a non-limiting example, the data bit line DBL 330 and the reference bit line RBL 332 are both pre-charged to VDD (e.g., logic 1) by the pre-charge circuit operatively formed of the transistors M9 to M11, prior to comparing respective signals (Q and QB signals) present on the data bit line DBL 330 and the reference bit line RBL 332. During such a pre-charge phase, the switches 340 and 342 are concurrently activated, and thus, the data bit line DBL 330 and the reference bit line RBL 332 can be concurrently coupled to the input nodes Qi and QBi of the sense amplifier 310, respectively.

The method 1100 continues to operation 1120 of discharging the data line and the reference line, with the first input node and the second input node remaining coupled to the data line and the reference line, respectively, and with the first input node and the second input node each decoupled from any transistor. Continuing with the above example, after the data bit line DBL 330 and the reference bit line RBL 332 are pre-charged to VDD, the transistors M9 to M11 (of the pre-charge circuit) are turned off, the transistors M3 to M6 of the sense amplifier 310 are turned off, and the switches 340-342 remain activated. Accordingly, the inputs nodes Qi and Qbi of the sense amplifier 310 are isolated from the transistors M1-M2 and M7-M8, but remain coupled to the data cell 320 and the reference cell 322 through the data bit line DBL 330 and the reference bit line RBL 332, respectively. As the switches 340 and 342 remain activated, the Q signal is equal to the Qi signal, and the QB signal is equal to the QBi signal.

The Q signal can correspond to the logic state of a first data bit stored in the data cell 320, and the QB signal can correspond to the logic state of a second data bit stored in the reference cell 322. In various embodiments, the first data bit is configured to be programmed with a first logic state, e.g., HRS, or a second logic state, e.g., LRS, while the second data bit is configured to be constantly programmed with a resistance state between the first and second logic states, e.g., (HRS+LRS)/2. As such, the Q signal and the QB signal can present respective voltage levels dropped from VDD with different voltage amounts. The voltage amounts can correspond to the different resistance states stored by the data cell 320 and the reference cell 322, respectively. For example, when the first data bit is programmed with the HRS and the second data bit is set at the (HRS+LRS)/2, the Q signal may drop from VDD with a slower discharging rate, when compared to a discharging rate of the QB signal. In another example, when the first data bit is programmed with the LRS and the second data bit is set at the (HRS+LRS)/2, the Q signal may drop from VDD with a faster discharging rate, when compared to a discharging rate of the QB signal.

The method 1100 continues to operation 1130 of latching a data bit stored by the data cell, with the first input node and the second input node decoupled from the data line and from the reference line, respectively. Continuing with the above example, after the QB signal (present on the reference bit line RBL 332) drops to a sufficiently voltage level, e.g., VDD/2, the transistors M3 to M6 can be turned on by the EN signal which is further triggered by the QB_DET signal. In some embodiments, the QB_DET signal may transition from logic 0 to logic 1, upon the QB signal dropping to a level around VDD/2. Concurrently with the QB_DET signal transitioning to logic 1, the switches 340 and 342 may be deactivated, e.g., by the SWEN signal. As a result, the input nodes Qi and QBi of the sense amplifier 310 are decoupled from the data bit line DBL 330 and the reference bit line RBL 332, respectively, and the transistors M1-M2 and M7-M8, which operatively serve as a pair of cross-coupled inverters, can latch and amplify the Q signal.

In one aspect of the present disclosure, a memory circuit is disclosed. The memory circuit includes a first memory cell configured to store a first data bit; a second memory configured to store a second data bit; a sense amplifier coupled to the first memory cell and the second memory cell through a data bit line and a reference bit line, respectively; a first switch; and a second switch. The first switch is selectively coupled between the data bit line and a first input node of the sense amplifier, and the second switch is selectively coupled between the reference bit line and a second input node of the sense amplifier.

In another aspect of the present disclosure, a memory circuit is disclosed. The memory circuit includes a sense amplifier configured to identify a data bit stored by a first memory cell, based on comparing a first signal present on a data bit line connecting the first memory cell to the sense amplifier and a second signal present on a reference bit line connecting a second memory cell to the sense amplifier; a first switch configured to selectively couple the data bit line to a first input node of the sense amplifier based on an enable signal; and a second switch configured to selectively couple the reference bit line to a second input node of the sense amplifier based on the enable signal.

In yet another aspect of the present disclosure, a method for operating memory circuits is disclosed. The method includes pre-charging a data bit line and a reference bit line to a first logic state, with the data bit line and the reference bit line coupled to a first input node and a second input node of a sense amplifier, respectively, wherein the data bit line is coupled to a data cell while the reference bit line is coupled to a reference cell. The method includes discharging the data bit line and the reference bit line, with the first input node and the second input node remaining coupled to the data bit line and the reference bit line, respectively, and with the first input node and the second input node each decoupled from any transistor. The method includes latching a data bit stored by the data cell, with the first input node and the second input node decoupled from the data bit line and from the reference bit line, respectively.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory circuit, comprising:
a first memory cell configured to store a first data bit;
a second memory cell configured to store a second data bit;
a sense amplifier coupled to the first memory cell and the second memory cell through a data bit line and a reference bit line, respectively;
a first switch; and
a second switch;
wherein the first switch is selectively coupled between the data bit line and a first input node of the sense amplifier, and the second switch is selectively coupled between the reference bit line and a second input node of the sense amplifier.

2. The memory circuit of claim 1, wherein the first data bit presents either a logic high state or a logic low state, and the second data bit is associated with a constant logic state between the logic high state and the logic low state.

3. The memory circuit of claim 1, wherein the first and second switches each include a transmission gate, a p-type transistor, or an n-type transistor.

4. The memory circuit of claim 1, wherein the sense amplifier further comprises:
a first transistor in p-type;
a second transistor in p-type;
a third transistor in p-type;
a fourth transistor in p-type;
a fifth transistor in n-type;
a sixth transistor in n-type;
a seventh transistor in n-type; and
an eighth transistor in n-type.

5. The memory circuit of claim 4, wherein the first, third, fifth, and seventh transistors are connected in series between a supply voltage and a ground voltage, and the second, fourth, sixth, and eighth transistors are connected in series between the supply voltage and the ground voltage.

6. The memory circuit of claim 5, wherein gate terminals of the first and seventh transistors are connected to the second input node, and gate terminals of the second and eighth transistors are connected to the first input node.

7. The memory circuit of claim 5, wherein gate terminals of the third and fourth transistors are configured to commonly receive a first control signal, and gate terminals of the fifth and sixth transistors are configured to commonly receive a second control signal logically opposite to the first control signal.

8. The memory circuit of claim 5, wherein the third and fifth transistors have their first source/drain terminals connected to each other at the first input node, and the fourth and sixth transistors have their first source/drain terminals connected to each other at the second input node.

9. The memory circuit of claim 5, wherein, during an evaluation phase of the sense amplifier, the third to sixth transistors are turned off, and the first, second, seventh, and eighth transistors are turned on, with the first and second switches being activated, thereby coupling the data bit line to the first input node and coupling the reference bit line to the second input node.

10. The memory circuit of claim 5, wherein, during a latch phase of the sense amplifier, the first to eighth transistors are turned on, with the first and second switches being deactivated, thereby decoupling the first input node from the data bit line and decoupling the second input node from the reference bit line.

11. The memory circuit of claim 1, wherein the first memory cell and the second memory cell each include a non-volatile memory cell.

12. A memory circuit, comprising:
a sense amplifier configured to identify a data bit stored by a first memory cell, based on comparing a first signal present on a data bit line connecting the first memory cell to the sense amplifier and a second signal present on a reference bit line connecting a second memory cell to the sense amplifier;
a first switch configured to selectively couple the data bit line to a first input node of the sense amplifier based on an enable signal; and
a second switch configured to selectively couple the reference bit line to a second input node of the sense amplifier based on the enable signal.

13. The memory circuit of claim 12, wherein the first memory cell and the second memory cell each include a non-volatile memory cell.

14. The memory circuit of claim 12, wherein the first signal corresponds to a logic high state or a logic low state, while the second signal corresponds to a logic state between the logic high state and the logic low state.

15. The memory circuit of claim 12, wherein the sense amplifier further comprises:
a first transistor in p-type;
a second transistor in p-type;
a third transistor in p-type;
a fourth transistor in p-type;
a fifth transistor in n-type;
a sixth transistor in n-type;
a seventh transistor in n-type; and
an eighth transistor in n-type.

16. The memory circuit of claim 15, wherein the first, third, fifth, and seventh transistors are connected in series between a supply voltage and a ground voltage, and the second, fourth, sixth, and eighth transistors are connected in series between the supply voltage and the ground voltage.

17. The memory circuit of claim 16, wherein, during an evaluation phase of the sense amplifier, the third to sixth transistors are turned off, and the first, second, seventh, and eighth transistors are turned on, with the first and second switches being activated, thereby coupling the data bit line to the first input node and coupling the reference bit line to the second input node.

18. A method for operating a memory circuit, comprising:
pre-charging a data bit line and a reference bit line to a first logic state, with the data bit line and the reference bit line coupled to a first input node and a second input node of a sense amplifier, respectively, wherein the data bit line is coupled to a data cell while the reference bit line is coupled to a reference cell;
discharging the data bit line and the reference bit line, with the first input node and the second input node remaining coupled to the data bit line and the reference bit line, respectively, and with the first input node and the second input node each decoupled from any transistor; and
latching a data bit stored by the data cell, with the first input node and the second input node decoupled from the data bit line and from the reference bit line, respectively.

19. The method of claim 18, wherein the data cell and the reference cell each include a non-volatile memory cell.

20. The method of claim 18, further comprising:
concurrently activating a first switch to couple the first input node to the data bit line and activating a second switch to couple the second input node to the reference bit line; or
concurrently deactivating the first switch decouple the first input node from the data bit line and deactivating the second switch to decouple the second input node from the reference bit line.
